(19) United States
(12) Patent Application Publication
(10) Pub. No.: US 2014/0179832 A1
(43) Pub. Date: Jun. 26, 2014

(54) EPOXY RESIN COMPOSITION FOR ENCAPSULATING A SEMICONDUCTOR DEVICE AND SEMICONDUCTOR DEVICE ENCAPSULATED USING THE SAME

(71) Applicant: Kyoung Chul BAE, Uiwang-si (KR)

(72) Inventor: Kyoung Chul BAE, Uiwang-si (KR)

(21) Appl. No.: 14/071,781

(22) Filed: Nov. 5, 2013

(30) Foreign Application Priority Data
Dec. 24, 2012 (KR) 10-2012-0152612

(51) Int. Cl. H01L 23/29

(52) U.S. Cl. CPC H01L 23/295
USPC 523/466

(57) ABSTRACT

The present invention provides an epoxy resin composition for encapsulating a semiconductor device, comprising: an epoxy resin, a curing agent, a curing accelerator, a coupling agent, and an inorganic filler, wherein the coupling agent comprises an alkylsilane compound represented by Formula 1:

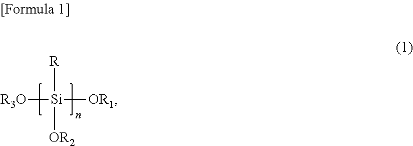

wherein R₁, R₂ and R₃ are each independently a C₁ to C₄ alkyl group, R is a C₆ to C₃₁ alkyl group, and n ranges from about 1 to 5 on average.

### CROSS-REFERENCE TO RELATED APPLICATION

Korean Patent Application No. 10-2012-0152612, filed on Dec. 24, 2012, in the Korean Intellectual Property Office, and entitled: “Epoxy Resin Composition For Encapsulating Semiconductor Device and Semiconductor Device Encapsulated Using the Same,” is incorporated by reference herein in its entirety.

### BACKGROUND

1. Field

Embodiments relate to an epoxy resin composition for encapsulating a semiconductor device and a semiconductor device encapsulated using the same.

2. Description of Related Art

As integration density of semiconductor devices has improved, miniaturization of interconnections, size diversification, and multilayered interconnections have been considered. Packages for protecting semiconductor devices from an external environment may be made compact and thin, in view of high density stacking on a print substrate, e.g., surface mounting technology.

### SUMMARY

Embodiments are directed to an epoxy resin composition for encapsulating a semiconductor device and a semiconductor device encapsulated using the same.

The embodiments may be realized by providing an epoxy resin composition for encapsulating a semiconductor device, the composition including an epoxy resin; a curing agent; a curing accelerator; a coupling agent; and an inorganic filler, wherein the coupling agent includes an alkylsilane compound represented by Formula 1:

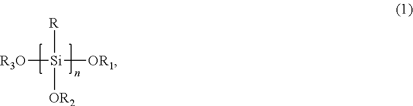

and

wherein R₁, R₂, and R₃ are each independently a C₁ to C₄ alkyl group, R is a C₆ to C₃₁ alkyl group, and n is about 1 to about 5 on average.

The alkylsilane compound may have a viscosity of about 40 mPa·s to about 60 mPa·s, as measured at 25° C. in a 50% methanol solution.

R₁, R₂, and R₃ may all be methyl groups.

The alkylsilane compound may have a specific gravity of about 0.7 to about 1.8, and a refractive index of about 0.85 to about 1.25.

The alkylsilane compound may be present in the composition in an amount of about 0.01 wt % to about 15 wt %, based on a total weight of the epoxy resin composition.

The alkylsilane compound may be present in the coupling agent in an amount of about 20 wt % to about 100 wt %, based on a total weight of the coupling agent.

The coupling agent may further includes at least one of an epoxysilane, an aminosilane, a mercaptosilane, or an alkoxysilane.

The composition may include about 1 wt % to about 20 wt % of the epoxy resin, about 0.01 wt % to about 20 wt % of the curing agent, about 0.001 wt % to about 5 wt % of the curing accelerator, about 0.01 wt % to about 15 wt % of the coupling agent, and about 70 wt % to about 94 wt % of the inorganic filler.

The embodiments may also be realized by providing a semiconductor device encapsulated using the epoxy resin composition according to an embodiment.

The alkylsilane compound may have a viscosity of about 40 mPa·s to about 60 mPa·s, as measured at 25° C. in a 50% methanol solution.

R₁, R₂, and R₃ may all be methyl groups.

The alkylsilane compound may have a specific gravity of about 0.7 to about 1.8, and a refractive index of about 0.85 to about 1.25.

The alkylsilane compound may be present in the composition in an amount of about 0.01 wt % to about 15 wt %, based on a total weight of the epoxy resin composition.

The alkylsilane compound may be present in the coupling agent in an amount of about 20 wt % to about 100 wt %, based on a total weight of the coupling agent.

The coupling agent may further includes at least one of an epoxysilane, an aminosilane, a mercaptosilane, or an alkoxysilane.

The composition may include about 1 wt % to about 20 wt % of the epoxy resin, about 0.01 wt % to about 20 wt % of the curing agent, about 0.001 wt % to about 5 wt % of the curing accelerator, about 0.01 wt % to about 15 wt % of the coupling agent, and about 70 wt % to about 94 wt % of the inorganic filler.

### BRIEF DESCRIPTION OF THE DRAWING

Features will be apparent to those of skill in the art by describing in detail exemplary embodiments with reference to the attached drawing in which:

FIG. 1 illustrates a semiconductor device encapsulated with an epoxy resin composition according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration.

An epoxy resin composition for encapsulating a semiconductor device according to an embodiment may include, e.g., an epoxy resin, a curing agent, a curing accelerator, a coupling agent, and inorganic fillers.

Now, each component of the epoxy resin composition will be described in detail.

Epoxy Resin

In the embodiments, the epoxy resin may include an epoxy resin that is suitable for encapsulating semiconductors. For example, the epoxy resin may include an epoxy compound having two or more epoxy groups. Examples of such an epoxy resin may include epoxy resins obtained by epoxidation of a condensate of a phenol or an alkyl phenol and a hydroxybenzaldehyde, phenol novolac type epoxy resins, ortho-cresol novolac type epoxy resins, biphenyl type epoxy resins, multifunctional epoxy resins, naphthol novolac type epoxy resins, novolac type epoxy resins of bisphenol A/bisphenol F/bisphenol AD, glycidyl ethers of bisphenol A/bisphenol F/bisphenol AD, bishydroxybiphenyl epoxy resins, dicyclopentadiene epoxy resins, and the like.

Examples of epoxy resins may include a phenol aralkyl type epoxy resins having a novolac structure including a biphenyl derivative represented by Formula 2, below.

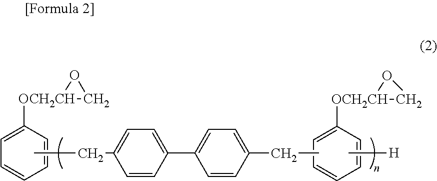

In Formula 2, n may be about 1 to about 7 on average.

The phenol aralkyl type epoxy resin represented by Formula 2 may have advantages in that the epoxy resin may have excellent moisture absorption, toughness, oxidative resistance, and crack resistance due to a biphenyl structure based on a phenol backbone. In addition, the epoxy resin may have low crosslinking density and thus may form a char layer upon combustion at high temperatures, which in turn may help provide flame retardancy. In an implementation, the epoxy resin may include about 10 wt % to about 90 wt % of the epoxy resin represented by Formula 2, based on a total weight of the epoxy resin. Within this range, the epoxy resin may have excellent balance between physical properties, and may not suffer from molding defects during a low pressure transfer molding process for encapsulating a semiconductor device. In an implementation, the epoxy resin may include about 20 wt % to about 70 wt %, e.g., about 30 wt % to about 50 wt %, of the epoxy resin represented by Formula 2, based on the total weight of the epoxy resin.

In an implementation, the epoxy resin may be a mixture of at least one selected from the group of an epoxy resin represented by Formula 2, an ortho-cresol novolac type epoxy resin, a biphenyl type epoxy resin, a bisphenol F type epoxy resin, a bisphenol A type epoxy resin, or a dicyclopentadiene type epoxy resin.

In an implementation, the epoxy resin may be used in combination with a biphenyl type epoxy resin represented by Formula 3, below.

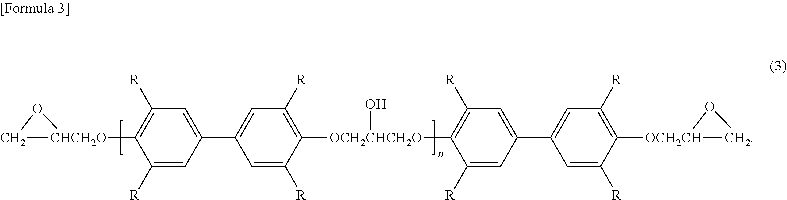

In Formula 3, R may be a C₁ to C₄ alkyl group, and n may be 0 to about 7 on average.

In an implementation, R may be a methyl group or an ethyl group, e.g., a methyl group.

The biphenyl type epoxy resin represented by Formula 3 may exhibit improved flowability and reliability.

The epoxy resins may be used alone or in combination thereof. Adducts such as a melt master batch obtained by pre-reacting an epoxy resin with other components, e.g., a curing agent, a curing accelerator, a release agent, a coupling agent, a stress relief agent, or the like, may be used. Further, advantageously, an epoxy resin containing a low amount of chlorine ions, sodium ions, and/or other ionic impurities may be used in order to help improve moisture resistance and reliability.

The epoxy resin may be present in the composition in an amount of about 1 wt % to about 20 wt %, e.g., about 3 wt % to about 15 wt % or about 5 to about 12 wt %, based on a total weight of the epoxy resin composition. Within this range, the resin composition may exhibit excellent flowability, adhesion, reliability, and moldability.

Curing Agent

The curing agent may include a compound that is suitable for encapsulating a semiconductor device, and is not particularly limited. The curing agent may include at least two phenolic hydroxyl groups or amino groups, or the like. The curing agent may include at least one of monomers, oligomers, and/or polymers.

Examples of the curing agent may include phenol aralkyl type phenol resins, Xylok type phenol resins, phenol novolac type phenol resins, cresol novolac type phenol resins, naphthol type phenol resins, terpene type phenol resins, multifunctional phenol resins, multi aromatic phenol resins, dicyclopentadiene phenol resins, terpene modified phenol resins, dicyclopentadiene modified phenol resins, novolac type phenol resins synthesized from bisphenol A and resol, tris(hydroxyphenyl)methane, multivalent phenol compounds containing dihydroxy biphenyl, acid anhydrides such as maleic anhydride and phthalic anhydride, aromatic amines such as m-phenylene diamine, diamino diphenyl methane, diamino diphenylsulfone, and the like, without being limited thereto.

In an implementation, the curing agent may include at least one selected from the group of a phenol aralkyl phenol resin having a biphenyl backbone represented by Formula 4, below, a phenol novolac type phenol resin represented by Formula 5, below, or a Xylok type phenol resin represented by Formula 6, below.

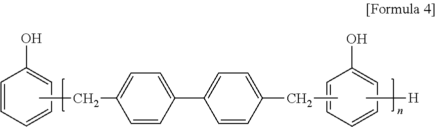

In Formula 4, n may be about 1 to about 7 on average.

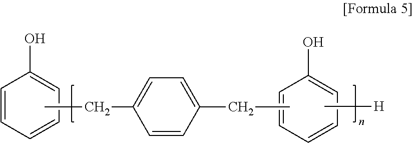

In Formula 5, n may be about 1 to about 7 in average.

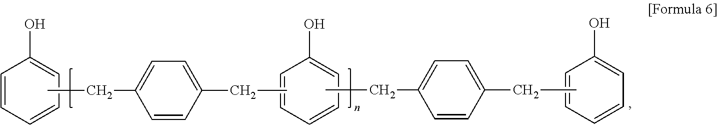

In Formula 6, n may be about 1 to about 7 on average.

The curing agent may be used alone or in combination thereof. For example, adducts such as melt master batch obtained by pre-reacting a curing agent with an epoxy resin, a curing accelerator, and other additives, may be used.

The curing agent may have a softening point of about 50° C. to about 100° C. Within this range, the epoxy resin composition may have suitable resin viscosity, thereby helping to reduce and/or prevent a deterioration in flowability.

The curing agent may have a phenolic hydroxyl group equivalent weight of about 90 g/eq to about 300 g/eq. For example, the Xylok type phenol resin may have a hydroxyl group equivalent weight of about 100 g/eq to about 200 g/eq; the phenol aralkyl type phenol resin may have a hydroxyl group equivalent weight of about 170 g/eq to about 300 g/eq, and/or the phenol novolac type phenol resin may have a hydroxyl group equivalent weight of about 90 g/eq to about 150 g/eq. Within this range, the resin composition may exhibit improved moldability and reliability.

Further, a component ratio of the epoxy resin to the curing agent may be selected such that a ratio of the epoxy group equivalent weight of the epoxy resin to the phenolic hydroxyl group equivalent weight of the curing agent is about 0.5:1 to about 2:1. Within this range of the equivalent ratio, the epoxy resin composition may help provide flowability without delaying curing time. In an implementation, the equivalent ratio may be about 0.8:1 to about 1.6:1.

The curing agent may be present in the composition in an amount of about 0.01 wt % to about 20 wt %, e.g., about 1 wt % to about 10 wt %, based on the total weight of the epoxy resin composition. Within this range, the resin composition may exhibit excellent reliability at least in part because unreacted epoxy groups and phenolic hydroxyl groups may not be generated in large amounts. In an implementation, the curing agent may be present in the composition in an amount of about 2 wt % to about 8 wt %, based on the total weight of the epoxy resin composition.

Curing Accelerator

The curing accelerator may help promote a reaction between the epoxy resin and the curing agent. Examples of the curing accelerator may include tertiary amines, organometallic or organic metal compounds, organophosphorus compounds, imidazole compounds, boron compounds, and the like, without being limited thereto. In an implementation, organophosphorus compounds may be used as the curing accelerator.

Examples of the tertiary amines may include benzyldimethylamine, triethanolamine, triethylenediamine, dimethylaminoethanol, tri(dimethylaminomethyl)phenol, 2-2-(dimethylaminomethyl)phenol, 2,4,6-tris(diaminomethyl)phenol, a salt of tri-2-ethylhexanoic acid, and the like, without being limited thereto. Examples of the organic metal compounds may include chromium acetylacetonate, zinc acetylacetonate, nickel acetylacetonate, and the like, without being limited thereto. Examples of the organophosphorus compounds may include tris-4-methoxyphosphine, tetrabutyl phosphonium bromide, butyl triphenyl phosphonium bromide, phenyl phosphine, diphenyl phosphine, triphenyl phosphine, triphenyl phosphine triphenyl borane, triphenyl phosphine-1,4-benzoquinone adducts, and the like, without being limited thereto. Examples of the imidazole compounds may include 2-methylimidazole, 2-phenylimidazole, 2-aminoimidazole, 2-methyl-1-vinylimidazole, 2-ethyl-4-methylimidazole, 2-heptadecylimidazole, and the like, without being limited thereto. Examples of the boron compounds may include tetraphenyl phosphonium tetraphenylborate, triphenyl phosphine tetraphenylborate, tetraphenylborate, trifluoroborane-n-hexylamine, trifluoroborane monoethylamine, tetrafluoroborane triethylamine, tetrafluoroborane amine, and the like, without being limited thereto. In an implementation, 1,5-diazobicyclo[4.3.0]non-5-ene, 1,8-diazobicyclo[5.4.0]undec-7-ene, and phenol novolac resin salts, and the like, may be used.

In addition, as the curing accelerator, adducts obtained by pre-reacting an epoxy resin and/or curing agent may also be used.

The curing accelerator may be present in the composition in an amount of about 0.01 wt % to about 5 wt %, based on the total weight of the epoxy resin composition. Within this range, the epoxy resin composition may exhibit flowability without delaying curing reaction time. In an implementation, the curing accelerator may be present in the composition in an amount of about 0.05 wt % to about 1 wt %.

Coupling Agent

The coupling agent may include a C₆ to C₃₁ alkylsilane compound represented by Formula 1, below

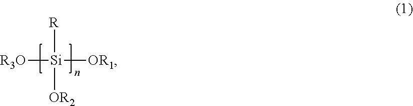

In Formula 1, R₁, R₂, and R₃ may each independently be a C₁ to C₄ alkyl group, R may be a C₆ to C₃₁ alkyl group, and n may be about 1 to about 5 on average.

In an implementation, R may be a C₁₂ to C₁₆ alkyl group and may have a linear structure. In such a case, the epoxy resin composition may exhibit further improved adhesion, moldability, and reliability.

In an implementation, n may be about 1.1 to about 3 on average.

The alkylsilane compound may be in liquid phase or liquid state at room temperature.

The alkylsilane compound may have a viscosity of about 40 mPa·s to about 60 mPa·s, e.g., about 50 mPa·s to about 58 mPa·s, as measured at 25° C. in a 50% methanol solution. Within this range, the epoxy resin composition may exhibit excellent adhesion and reliability.

In an implementation, R₁, R₂, and R₃ may all be methyl groups.

In an implementation, the alkylsilane compound may have a specific gravity of about 0.7 to about 1.8, e.g., about 0.9 to about 1.2. In an implementation, the alkylsilane compound may have a refractive index of about 0.85 to about 1.25, e.g., about 0.95 to about 1.1.

In an implementation, the alkylsilane compound may be present in the composition in an amount of about 0.01 wt % to about 15 wt %, e.g., about 0.1 wt % to about 1.5 wt % or about 0.3 wt % to about 1 wt %, based on the total weight of the epoxy resin composition.

The coupling agent may be employed together with another coupling agent, e.g., an epoxysilane, an aminosilane, a mercaptosilane, an alkoxysilane, or the like, in addition to the alkylsilane compound. In an implementation, the alkylsilane compound may be present in the coupling agent in an amount of about 20 wt % to about 100 wt %, e.g., about 50 wt % to about 95 wt %, based on a total weight of the coupling agent.

In an implementation, the coupling agent may include a mixture of the alkylsilane compound and methyl silane. In this case, the alkylsilane compound and the methyl silane may be mixed in a weight ratio of about 10:1 to about 25:1.

In an implementation, the coupling agent may include a mixture of the alkylsilane compound with methyl silane and mercaptosilane. In this case, the alkylsilane compound, methyl silane, and mercaptosilane may be mixed in a weight ratio of about 60˜75:10˜25:1˜15.

In an implementation, the coupling agent may include a mixture of the alkylsilane compound with methyl silane, mercaptosilane, and epoxysilane. In this case, the alkylsilane compound, methyl silane, mercaptosilane, and epoxysilane may be mixed in weight ratio of about 50˜80:1˜15:10˜25:5˜25.

The coupling agent may be present in the composition in an amount of about 0.01 wt % to about 15 wt %, e.g., about 0.1 wt % to about 10 wt % or about 0.2 wt % to about 1.2 wt %, based on the total weight of epoxy resin composition.

Inorganic Filler

Inorganic fillers may be included in the epoxy resin composition to help improve mechanical properties while lowering strain. Examples of the inorganic fillers may include fused silica, crystalline silica, calcium carbonate, magnesium carbonate, alumina, magnesia, clay, talc, calcium silicate, titanium oxide, antimony oxide, glass fiber, and the like, without being limited thereto. The inorganic fillers may be used alone or in combination of two or more thereof.

In an implementation, fused silica having a low coefficient of linear expansion may be used in order to help lower strain. Fused silica refers to non-crystalline silica having a specific gravity of 2.3 or less. Fused silica may be produced by melting crystalline silica or may include non-crystalline silica synthesized from various materials.

A shape and a particle diameter of inorganic fillers are not particularly limited. The inorganic fillers may have an average particle diameter of about 0.001 μm to about 30 μm. In an implementation, spherical fused silica having an average particle diameter of about 0.001 μm to about 30 μm may be used. In an implementation, the inorganic filler may include a mixture of spherical fused silica having different particle diameters. For example, the inorganic fillers may include a mixture of about 50 wt % to about 99 wt % of spherical fused silica having an average particle diameter from 5 μm to 30 μm and about 1 wt % to about 50 wt % of spherical fused silica having an average particle diameter from 0.001 μm to 1 μm. In an implementation, a maximum particle diameter of the inorganic fillers may be adjusted to be about 45 μm, about 55 μm, or about 75 μm, depending on application.

In an implementation, the inorganic fillers may be subjected to surface treatment with at least one coupling agent selected from the group of epoxysilane, aminosilane, mercaptosilane, alkylsilane, or alkoxysilane.

The inorganic fillers may be included in the composition in a suitable ratio or amount, according to desired physical properties of the epoxy resin composition, e.g., moldability, low strain, and high temperature strength. For example, the inorganic fillers may be included in the composition in an amount of about 70 wt % to about 94 wt %, based on the total weight of the epoxy resin composition. Within this range, the resin composition may exhibit excellent flexural strength and package reliability. In an implementation, the inorganic fillers may be included in an amount of about 80 wt % to about 90 wt % in the epoxy resin composition.

Additive

The epoxy resin composition may further include an additive. The additive may include, e.g., a coloring agent, a release agent, a stress relief agent, a crosslinking promoter, a leveling agent, a flame retardant, or the like.

Examples of the coloring agent may include carbon black, and organic or inorganic dyes, without being limited thereto.

The release agent may include at least one selected from the group of paraffin wax, ester wax, high fatty acids, high fatty acid metal salts, natural fatty acids, and natural fatty acid metal salts, without being limited thereto.

The stress relief agent may include at least one selected from the group of modified silicone oil, silicone elastomers, silicone powder, and silicone resin, without being limited thereto.

The additive may be included in the composition in an amount of about 0.1 wt % to about 5.5 wt %.

The epoxy resin composition may further include a flame retardant. Examples of the flame retardant may include non-halogen organic or inorganic flame retardants. The non-halogen organic or inorganic flame retardants may include, e.g., phosphagene, zinc borate, aluminum hydroxide, magnesium hydroxide, or the like, without being limited thereto.

Flame retardancy may differ depending on a content of the inorganic fillers and the kind of curing agent. Thus, the flame retardant may be included in the epoxy resin composition in a suitable ratio or amount, according to desired flame retardancy. In an implementation, the flame retardant may be included in the composition in an amount of about 0 to about 10 wt %, e.g., about 0 to about 8 wt % or less or about 0 to about 5 wt % or less, based on the total weight of the epoxy resin composition.

A method for producing the epoxy resin composition according to an embodiment is not particularly limited. For example, the epoxy resin composition may be produced by uniformly mixing the components using a Henschel mixer or a Ploughshare mixer, followed by melt kneading at about 90° C. to about 120° C. using a roll mill or a kneader, and cooling and pulverizing the resultant.

A method for encapsulating a semiconductor device using the epoxy resin composition may be generally performed by low pressure transfer molding. However, compression molding, injection molding, or cast molding may also be performed. By the aforementioned processes, semiconductor devices including a copper lead frame, an iron lead frame, or a lead frame obtained by pre-plating at least one selected from nickel, copper, or palladium onto the lead frame, or an organic laminate frame may be produced.

The embodiments provide a semiconductor device encapsulated using the epoxy resin composition described above. For example, the epoxy resin composition according to an embodiment may exhibit excellent adhesion, moldability, reliability, moisture resistance, and/or crack resistance, and thus may be favorably employed in encapsulation of multichip packages.

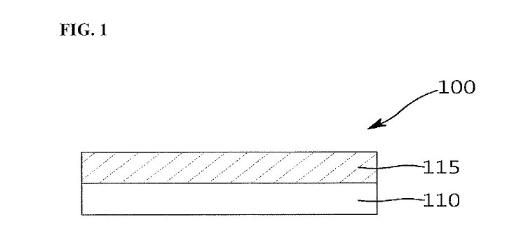

FIG. 1 illustrates a semiconductor device encapsulated with an epoxy resin composition according to an embodiment. For example, the semiconductor device 100 encapsulated with the epoxy resin composition may include a lead frame 110 and an encapsulant 115 (prepared from the epoxy resin composition according to an embodiment) on the lead frame 110.

A procedure for encapsulating the packages is not particularly limited. For example, the procedure may include encapsulating a semiconductor device using the prepared epoxy resin composition, and post-molding curing the encapsulated semiconductor device package. Encapsulation may be carried out at about 160° C. to about 190° C. for about 40 seconds to about 300 seconds, and post-molding curing may be carried out at about 160° C. to about 190° C. for about 0 to 8 hours.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

Details of the components used in Examples and Comparative Examples are as follows.

(A) Epoxy resin

(a1) Biphenyl type epoxy resin: YX-4000H, JER, epoxy equivalent weight: 190

(a2) Phenol aralkyl type epoxy resin: NC-3000 (Nippon Kayaku K.K.), epoxy equivalent weight: 270

(B) Curing agent

(b 1) Xylok type phenol resin: MEH-7800-4S (Meiwa Chem.), hydroxyl group equivalent weight: 175

(b2) Phenol aralkyl type phenol resin: MEH-7851-SS (Meiwa Chem.), hydroxyl group equivalent weight: 200

(b3) Phenol novolac type phenol resin: H-4 (Meiwa Chem.), hydroxyl group equivalent weight: 106

(C) Curing accelerator: Triphenylphosphine (TPP) (Hokko)

(D) Coupling agent

(d1) Epoxysilane: γ-glycidoxypropyl trimethoxysilane, KBM-403 (Shinetsu silicon)

(d2) Mercaptosilane: Mercaptopropyl trimethoxysilane, KBM-803 (Shinetsu silicon)

(d3) Methylsilane: Methyltrimethoxysilane, SZ-6070 (Dow Corning Chemical)

(d4) Alkylsilane compound: Dynasylan-9896 (Evonik-Degussa GmbH), viscosity: 55 mPa·s, specific gravity: 1.04, refractive index: 1.03

(E) Inorganic filler: 9:1 mixture of spherical fused silica having an average particle diameter of 20 μm and spherical fused silica having an average particle diameter of 0.5 μm

(F) Additive:

(f1) Carnauba wax as a release agent

(f2) Carbon black MA-600 (Matsushita Chemical) as a coloring agent

(f3) Silicone powder as a stress relief agent

(f4) 1:1 mixture of antimony trioxide and brominated epoxy resin (BREN-S, Nippon Kayaku K.K.) as a flame retardant.

### Examples 1 to 4 and Comparative Examples 1 to 3

The components were weighed in amounts as listed in Table 1, below, and uniformly mixed using a Henschel mixer to prepare a primary composition in a powder state. Subsequently, the composition was melt kneaded at 95° C. using a continuous kneader, followed by cooling and pulverizing to prepare an epoxy resin composition for encapsulating a semiconductor device.

TABLE 1

| | | Example | | | | Comparative Example | | |
|---|---|---|---|---|---|---|---|---|
| | | 1 | 2 | 3 | 4 | 1 | 2 | 3 |
| (A) Epoxy | (a1) | 2.92 | 2.92 | 2.92 | 2.92 | 2.92 | 2.92 | 2.92 |
| resin | (a2) | 2.72 | 2.72 | 2.72 | 2.72 | 2.72 | 2.72 | 2.72 |
| (B) Curing | (b1) | 2.54 | 2.54 | 2.54 | 2.54 | 2.54 | 2.54 | 2.54 |
| agent | (b2) | 1.44 | 1.44 | 1.44 | 1.44 | 1.44 | 1.44 | 1.44 |
| | (b3) | 1.00 | 1.00 | 1.00 | 1.00 | 1.00 | 1.00 | 1.00 |
| (C) Curing | | 0.17 | 0.17 | 0.17 | 0.17 | 0.17 | 0.17 | 0.17 |
| accelerator | | | | | | | | |
| (D) | (d1) | — | — | 0.08 | 0.16 | 0.16 | 0.80 | 0.08 |
| Coupling | (d2) | 0.08 | — | 0.12 | 0.16 | 0.04 | — | 0.68 |
| agent | (d3) | 0.16 | 0.04 | 0.04 | 0.08 | 0.6 | — | 0.04 |
| | (d4) | 0.56 | 0.76 | 0.56 | 0.4 | — | — | — |
| (E) Inorganic | | 86.73 | 86.73 | 86.73 | 86.73 | 86.73 | 86.73 | 86.73 |
| filler | | | | | | | | |
| (F) | (f1) | 0.16 | 0.16 | 0.16 | 0.16 | 0.16 | 0.16 | 0.16 |
| Additive | (f2) | 0.22 | 0.22 | 0.22 | 0.22 | 0.22 | 0.22 | 0.22 |
| | (f3) | 0.30 | 0.30 | 0.30 | 0.30 | 0.30 | 0.30 | 10.30 |
| | (f4) | 1.0 | 1.0 | 1.0 | 1.0 | 1.0 | 1.0 | 1.0 |

Physical properties and reliability of the prepared epoxy resin compositions were evaluated as follows. Physical property evaluation results for the epoxy resin compositions are shown in Table 2, below.

<Evaluation of Physical Properties>

(1) Flowability (inch): Flow length was measured at 175° C. under a load of 70 kgf/cm² using an evaluation mold and a transfer molding press in accordance with EMMI-1-66. Higher values indicate better flowability.

(2) Glass transition temperature (° C.): Glass transition temperature was measured using a thermo-mechanical analyzer (TMA) under the condition that temperature was increased from 25° C. to 300° C. at a heating rate of 10° C./min.

(3) Coefficient of thermal expansion (μm/m, ° C.): Coefficient of thermal expansion was measured in accordance with ASTM D696.

(4) Adhesion (kgf): Specimens on which silver, copper, and nickel-palladium were plated, respectively, were prepared. To these metal specimens, the resin compositions prepared according to the Examples and Comparative Examples were applied and molded under the condition of a mold temperature of 170° C.˜180° C., a transfer pressure of 1,000 psi, a transfer speed of 0.5˜1 cm/s and a curing duration of 120 seconds to obtain cured specimens. The obtained specimens was subjected to post-molding curing (PMC) by placing the specimens in an oven at 170° C. to 180° C. for 4 hours, followed by passing through IR reflow once at 260° C. for 30 seconds. PMC and IR reflow were repeated three times (pre-conditioning treatment). Adhesion after pre-conditioning treatment was measured. Further, after PMC, the specimens were left at 85° C. and 85% relative humidity for 168 hours. Adhesion after the same pre-conditioning treatment as above was measured. The area of the epoxy resin composition contacting the specimen was 40±1 mm². Adhesion was measured using a universal testing machine (UTM) with respect to 12 specimens and an average value thereof was calculated.

(5) Flexural strength and flexural modulus: Standard specimens were prepared in accordance with ASTM D-790, cured at 175° C. for 4 hours, and then flexural strength and flexural modulus were measured using a UTM (kgf/mm² at 260° C.).

(6) Moisture absorption rate (wt %): The resin compositions prepared according to the Examples and Comparative Examples were molded under conditions of a mold temperature of 170° C.˜180° C., a clamp pressure of 70 kgf/cm², a transfer pressure of 1,000 psi, a transfer speed of 0.5˜1 cm/s, and a curing duration of 120 seconds to obtain disc-shaped cured specimens having a diameter of 50 mm and a thickness of 1 mm. The obtained specimens were subjected to post-molding curing by placing the specimens in an oven at 170° C.˜180° C. for 4 hours and then left at 121° C. and 100 RH % for 24 hours. Weight change due to moisture absorption was measured and moisture absorption rate was calculated by Equation 1, below.

Moisture absorption rate={(Weight of specimen after moisture absorption−Weight of specimen before moisture absorption)÷(Weight of specimen before moisture absorption)}×100

(7) Reliability: After pre-conditioning treatment and 1,000 cycles in the Temperature Cycle Test, the specimens were evaluated as to the occurrence of cracks or delamination using scanning acoustic tomography (SAT), which is a non-destructive inspection test method.

a) Condition for Pre-Conditioning Treatment

A multichip package prepared from the epoxy resin composition was dried at 125° C. for 24 hours, and then subjected to 5 cycles of temperature cycle testing. Then, the multichip package was left at 85° C. and 85% RH for 96 hours and passed through IR reflow once at 260° C. for 30 seconds. After repeating this procedure three times (pre-conditioning), the occurrence of cracking in the package was evaluated. When cracking occurred at this stage, 1,000 cycles of temperature cycle testing were not performed.

b) Temperature Cycle Test

The multichip package, after passing through pre-conditioning treatment, was left at −65° C. for 10 minutes, 25° C. for 5 minutes, and 150° C. for 10 minutes (1 cycle). After 1,000 cycles, the package was evaluated as to inside and outside cracking using SAT.

c) Reliability Test

In order to measure reliability, semiconductor chips were molded by the epoxy resin compositions in a multi plunger system (MPS) at 175° C. for 70 seconds, and subjected to post-molding curing at 175° C. for 2 hours to prepare multichip packages wherein four semiconductor chips were stacked using an organic adhesive film, respectively. Reliability is represented as the number of cracks after preconditioning and temperature cycle testing, and the number of delaminated sections after temperature cycle testing.

(8) Moldability: Semiconductor chips were molded by the epoxy resin compositions in a multi plunger system (MPS) at 175° C. for 70 seconds, and subjected to post-molding curing at 175° C. for 2 hours to prepare multichip packages (14 mm×18 mm×1.6 mm) wherein four semiconductor chips were stacked using an organic adhesive film, respectively. Subsequently, number of voids in the packages was evaluated with the naked eye. The multichip has a thickness of 0.85 mm. After filling the packages with the molding materials, all of the packages were processed to a thickness of 1.6 mm for evaluation. The total number of packages tested was 256.

TABLE 2

| | | | Example | | | | Comparative Example | | |
|---|---|---|---|---|---|---|---|---|---|
| Evaluation | | | 1 | 2 | 3 | 4 | 1 | 2 | 3 |
| Flowability (inch) | | | 47 | 52 | 50 | 49 | 48 | 47 | 46 |
| Tg (° C.) | | | 132 | 131 | 133 | 134 | 135 | 136 | 133 |
| Coefficient of thermal expansion | | | 10.5 | 10.3 | 10.2 | 10.5 | 10.4 | 10.5 | 10.7 |
| Adhesion | Silver | Immediately after | 65 | 70 | 67 | 64 | 37 | 34 | 37 |
| | | PMC | | | | | | | |
| | | After | 42 | 44 | 35 | 39 | 16 | 9 | 12 |
| | | 85RH*85° C.*168 | | | | | | | |
| | | hrs | | | | | | | |
| | Copper | After PMC | 51 | 53 | 49 | 50 | 28 | 26 | 31 |
| | | After | 34 | 36 | 36 | 34 | 15 | 13 | 10 |
| | | 85RH*85° C.*168 | | | | | | | |
| | | hrs | | | | | | | |
| | Ni*Pd | Immediately after | 83 | 81 | 74 | 79 | 20 | 19 | 13 |
| | (PPF) | PMC | | | | | | | |
| | | After | 34 | 31 | 40 | 36 | 10 | 11 | 7 |
| | | 85RH*85° C.*168 | | | | | | | |
| | | hrs | | | | | | | |

| Flexural strength | | 1.4 | 1.5 | 1.5 | 1.5 | 1.1 | 1.2 | 1.3 |
|---|---|---|---|---|---|---|---|---|
| Flexural modulus | | 65 | 62 | 66 | 61 | 75 | 85 | 73 |
| Moisture absorption rate | | 0.203 | 0.197 | 0.205 | 0.198 | 0.244 | 0.256 | 0.251 |
| Reliability | Crack resistance | 0 | 0 | 0 | 0 | 9 | 6 | 11 |
| | (Temperature Cycle Test) | | | | | | | |
| | Number of cracks | | | | | | | |
| | Number of delaminated | 0 | 0 | 0 | 0 | 25 | 32 | 11 |
| | sections | | | | | | | |
| | Number of packages tested | 240 | 240 | 240 | 240 | 240 | 240 | 240 |
| Moldability | Number of voids | 0 | 0 | 0 | 0 | 21 | 11 | 42 |
| | Number of packages tested | 256 | 256 | 256 | 256 | 256 | 256 | 256 |

As may be seen in Table 2, the resin compositions prepared in Examples 1 to 4 exhibited better adhesion, reliability, and moldability, higher flexural strength and lower moisture absorption rate than the compositions prepared in Comparative Examples 1 to 3.

By way of summation and review, in a resin encapsulated semiconductor apparatus in which a semiconductor device is encapsulated in a compact and thin package, package cracking, delamination, aluminum pad corrosion, or the like may occur due to, e.g., heat strain according to changes in temperature and humidity of an external environment. A method of addressing package cracking or delamination may include high reliability enhancement of molding materials for encapsulating epoxy resin. For example, a method of enhancing adhesion with metal devices, a method of lowering storage modulus for low stress, a method of lowering a coefficient of thermal expansion, or the like have been considered. Further, a method of inhibiting corrosion may include decreasing an amount of impurities using a high purity epoxy resin or curing agent, or an ion trap, and a moisture absorption rate may be decreased by providing a high amount of inorganic fillers.

A method of improving adhesion with metal devices may include using low viscosity resins or adhesion enhancement agents to improve adhesion.

A method of lowering storage modulus may include using an epoxy resin molding material prepared using a silicone polymer, which has improved thermal stability modified using various rubber components. In such a method, silicone oil may have no compatibility with the curing agent and the epoxy resin used as a base resin for the molding material. Thus, the silicone oil may be dispersed in micro-particle form in the base resin, thereby attaining low storage modulus while maintaining heat resistance.

Furthermore, for low thermal expansion, a method of increasing the filling amount of inorganic fillers having a low coefficient of thermal expansion has been considered. In this case, with an increase of the filling amount of inorganic fillers, low flowability and high elasticity of the epoxy resin molding material may occur. Accordingly, a technology for compounding a large amount of fillers through adjustment of particle size distribution and particle size may be used.

However, package cracking or delamination may occur.

To attain small, thin and high performance semiconductor devices, multichip packaging, in which several semiconductor chips are stacked vertically, has been considered. In a multichip package, an organic die-attach film (DAF) may be used to attach one chip to another. In this case, attachment between the chips may exhibit very poor reliability, as compared with a case in which a semiconductor chip is attached to a metal pad via metal pastes as a kind of chip adhesives. For example, delamination between the chip and the attach film may occur due to poor adhesion of the organic die-attach film, and package cracking may easily occur due to poor moisture resistance of the organic die-attach film.

The embodiments may provide an epoxy resin composition having excellent reliability in tennis of package cracking or delamination by enhancing adhesion to metal devices, high flowability upon multi-chip filling, and excellent moldability without creating voids.

The embodiments may provide an epoxy resin composition for encapsulating a semiconductor device, which includes a coupling agent of a particular structure to provide excellent moldability and high reliability.

The embodiments may provide an epoxy resin composition for encapsulating a semiconductor device and having excellent moldability and reliability and being capable of improving adhesion, moisture resistance, crack resistance, and tensile properties by improving adhesion, lowering moisture absorption rate and coefficient of thermal expansion, improving mechanical elasticity while inhibiting voids upon molding multichip packages.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulating a semiconductor device, the composition comprising:
an epoxy resin;
a curing agent;
a curing accelerator;
a coupling agent; and
an inorganic filler,
wherein the coupling agent includes an alkylsilane compound represented by Formula 1: 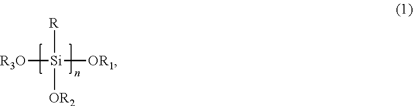
and
wherein R₁, R₂, and R₃ are each independently a C₁ to C₄ alkyl group, R is a C₆ to C₃₁ alkyl group, and n is about 1 to about 5 on average.

2. The epoxy resin composition as claimed in claim 1, wherein the alkylsilane compound has a viscosity of about 40 mPa·s to about 60 mPa·s, as measured at 25° C. in a 50% methanol solution.

3. The epoxy resin composition as claimed in claim 1, wherein R₁, R₂, and R₃ are all methyl groups.

4. The epoxy resin composition as claimed in claim 1, wherein the alkylsilane compound has a specific gravity of about 0.7 to about 1.8, and a refractive index of about 0.85 to about 1.25.

5. The epoxy resin composition as claimed in claim 1, wherein the alkylsilane compound is present in the composition in an amount of about 0.01 wt % to about 15 wt %, based on a total weight of the epoxy resin composition.

6. The epoxy resin composition as claimed in claim 1, wherein the alkylsilane compound is present in the coupling agent in an amount of about 20 wt % to about 100 wt %, based on a total weight of the coupling agent.

7. The epoxy resin composition as claimed in claim 1, wherein the coupling agent further includes at least one of an epoxysilane, an aminosilane, a mercaptosilane, or an alkoxysilane.

8. The epoxy resin composition as claimed in claim 1, wherein the composition includes:
about 1 wt % to about 20 wt % of the epoxy resin,
about 0.01 wt % to about 20 wt % of the curing agent,
about 0.001 wt % to about 5 wt % of the curing accelerator,
about 0.01 wt % to about 15 wt % of the coupling agent, and
about 70 wt % to about 94 wt % of the inorganic filler.

9. A semiconductor device encapsulated using the epoxy resin composition as claimed in claim 1.

10. The semiconductor device as claimed in claim 9, wherein the alkylsilane compound has a viscosity of about 40 mPa·s to about 60 mPa·s, as measured at 25° C. in a 50% methanol solution.

11. The semiconductor device as claimed in claim 9, wherein R₁, R₂, and R₃ are methyl groups.

12. The semiconductor device as claimed in claim 9, wherein the alkylsilane compound has a specific gravity of about 0.7 to about 1.8, and a refractive index of about 0.85 to about 1.25.

13. The semiconductor device as claimed in claim 9, wherein the alkylsilane compound is present in the composition in an amount of about 0.01 wt % to about 15 wt %, based on a total weight of the epoxy resin composition.

14. The semiconductor device as claimed in claim 9, wherein the alkylsilane compound is present in the coupling agent in an amount of about 20 wt % to about 100 wt %, based on a total weight of the coupling agent.

15. The semiconductor device as claimed in claim 9, wherein the coupling agent further includes at least one of an epoxysilane, an aminosilane, a mercaptosilane, or an alkoxysilane.

16. The semiconductor device as claimed in claim 9, wherein the composition includes:
about 1 wt % to about 20 wt % of the epoxy resin,
about 0.01 wt % to about 20 wt % of the curing agent,
about 0.001 wt % to about 5 wt % of the curing accelerator,
about 0.01 wt % to about 15 wt % of the coupling agent, and
about 70 wt % to about 94 wt % of the inorganic filler.
